(19) United States
(12) Patent Application Publication
(10) Pub. No.: US 2002/0196010 A1
(43) Pub. Date: Dec. 26, 2002

(54) Method of determining a resistive current

(75) Inventor: Jerry F. Adams, Waterport, NY (US)

Correspondence Address: Patent Documentation Center, Xerox Corporation, Xerox Square 20th Floor, 100 Clinton Ave. S., Rochester, NY, 14644, US

(73) Assignee: Xerox Corporation

(21) Appl. No.: 09/886,766

(22) Filed: Jun. 21, 2001

(51) Int. Cl. G01R 23/00; G01R 23/12

(52) U.S. Cl. 324/76.52

(57) ABSTRACT

A xerographic charging device corona current is determined by forming a first signal across a sense resistor in series with the charging device power supply, forming a second signal using a resistive voltage divider network across the power supply, and forming a third signal using a resistor-capacitor charging circuit across the power supply, and then processing the first, second and third signals to form an output signal that is based on the corona current.

### TECHNICAL FIELD

This invention relates to a method of determining a resistive current and more particularly to a method of determining a corona current in a xerographic charging device.

### BACKGROUND OF THE INVENTION

There are many applications where a load current includes both a resistive current component and a capacitive current component. In some applications it is desirable to measure both the resistive component and the capacitive current component where the resistance, capacitance, or both, are unknown or varying.

One such application is a xerographic charging device driven by an AC power supply. Here the load current is the corona current, which comprises both a resistive component and also a parasitic capacitive component. If the resistive and capacitive current components can be measured without knowledge of the absolute or relative values of either the resistance or capacitance of the load, the information can be used to control the AC power supply to ensure improved corona charging performance.

### SUMMARY OF THE INVENTION

In one embodiment, a load current comprises a resistive current and a capacitive current. The load is driven by a sinusoidal input signal. The resistive current is determined by forming a first signal that is substantially in-phase with and proportional to the sum of the resistive current and the capacitive current; forming a second signal in-phase with the input signal; forming a third signal opposite in phase to the capacitive current; and processing the first, second and third signals to form a result based on the resistive current.

In a further embodiment, a load current comprises a resistive current and a capacitive current. The load is driven by an input signal. The resistive current is determined by forming a first signal in-phase with and proportional to the sum at all frequencies comprised in the input signal of the resistive current and the capacitive current; forming a second signal in-phase with the input signal; forming a third signal proportional to the capacitive current at all frequencies comprised in the input signal; and processing the first, second and third signals to form a result based on the resistive current.

### BRIEF DESCRIPTION OF THE DRAWING

FIG. 1 depicts an input signal 10 arranged to drive a load 100, the load 100 comprising a resistive current, I_{R}, and a capacitive current, I_{X}.

FIG. 2 depicts an input signal 210 and the FIG. 1 load 100 arranged to form a first signal 201, a second signal 202 and a third signal 203. The FIG. 2 first, second and third signals 201-203 are then input to a processor 300.

FIG. 3 depicts the FIG. 2 processor 300 in greater detail. As shown, the processor 300 includes a phase detector 310.

FIG. 4 depicts the FIG. 3 phase detector 310 and the identical FIG. 6 phase detector 610.

FIG. 5 depicts an input signal 510 and the FIG. 1 load 100 arranged to form a first signal 501, a second signal 502 and a third signal 503. The FIG. 5 first, second and third signals 501-503 are then input to a processor 600.

FIG. 6 depicts the FIG. 5 processor 600 in greater detail. As shown, the processor 600 includes a phase detector 610.

FIG. 7 depicts one embodiment of the FIG. 3 summing circuit 330 and the FIG. 6 summing circuit 630.

FIG. 8 depicts one embodiment of the FIG. 4 first comparator 411 and second comparator 412.

FIG. 9 depicts one embodiment of the FIG. 4 amplifier 440.

FIG. 10 depicts one embodiment of the FIG. 6 low-pass filter 640.

FIG. 11 depicts one embodiment of the FIG. 3 buffer amplifier 340, the FIG. 5 buffer amplifier 570, and the FIG. 6 buffer amplifier 650.

### DETAILED DESCRIPTION OF THE INVENTION

Briefly, a xerographic charging device corona current is determined by forming a first signal across a sense resistor in series with the charging device power supply, forming a second signal using a resistive voltage divider network across the power supply, and forming a third signal using a resistor-capacitor charging circuit across the power supply, and then processing the first, second and third signals to form an output signal that is based on the corona current.

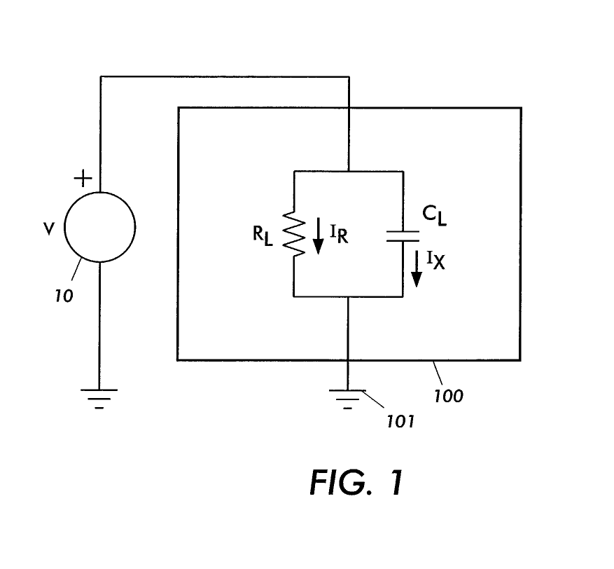

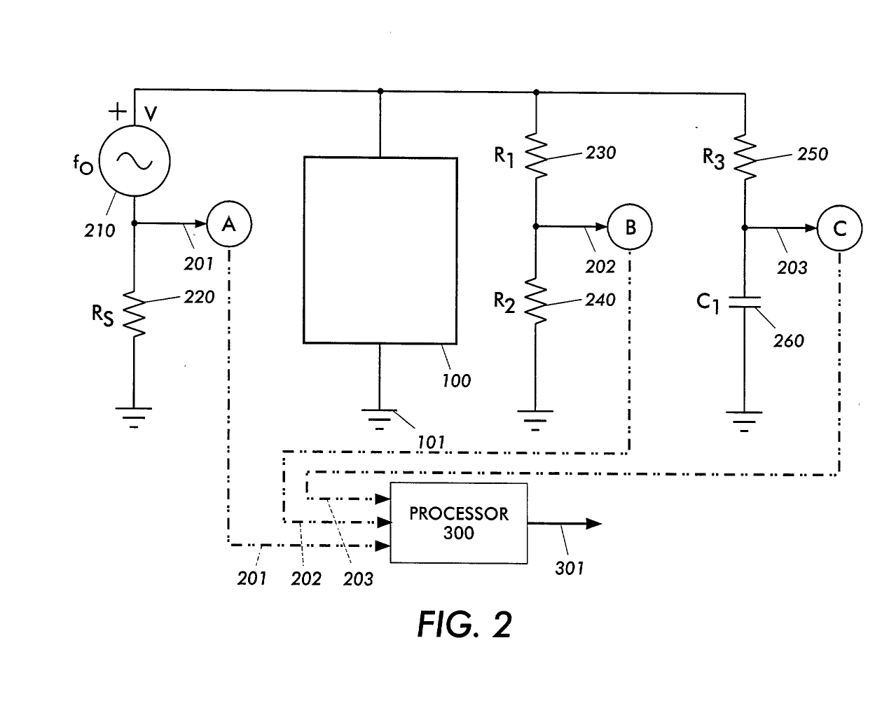

Referring to FIG. 1, there is depicted a input signal 10 arranged to drive a load 100, the load comprising a resistive current, I_{R}, and a capacitive current, I_{X}. In one embodiment, the load 100 comprises a xerographic charging device and the resistive current, I_{R}, comprises the corona charging current. In FIG. 1 the input signal 10 generally depicts a sinusoidal signal 210 as discussed in FIG. 2 below, a non-sinusoidal signal 510 as discussed in FIG. 5 below, or both.

Referring to FIG. 2, there is depicted the input signal 210, comprising a sinusoidal input signal of frequency f₀, and the FIG. 1 load 100 arranged for determining the resistive current, I_{R}.

A first signal 201 is formed based on a sense resistor 220 (R_{S}) coupled in series with the input signal 210. This first signal 201 is substantially in-phase with and proportional to the sum of the resistive current, I_{R}, and the capacitive current, I_{X}.

A second signal 202 is formed based on a resistive voltage-divider network comprising resistor 230 (R₁) and resistor 240 (R₂) coupled from the input signal 210 to ground 101. This second signal 202 is in-phase with the input signal 210.

A third signal 203 is formed based on a resistor-capacitor network comprising resistor 250 (R₃) and capacitor 260 (C₁) coupled from the input signal 210 to ground 101. This third signal 203 is opposite in phase to the capacitive current, I_{X}.

The FIG. 2 first, second and third signals 201-203 are then input to a processor 300 which forms a first result 301 that is proportional to the resistive current, I_{R}.

In one embodiment:

The input signal 210 comprises a sinusoidal signal of magnitude of 6 Kilo volts RMS at a frequency (f₀) of 4 KHz.

The load resistance R_{L}, comprising the load charging device 100 corona charging resistance, comprises 500 K-Ohms.

The load capacitance C_{L}, comprising the load charging device 100 parasitic capacitance, comprises 10 pF.

The sense resistor, R_{S}, comprises 100 ohms, which is much less than R_{L}.

The resistor R₁ is 10 Meg-Ohms, and the resistor R₂ is 10 K-Ohms. Thus, the sum of resistor R₁ and resistor R₂ is much greater than R_{L}.

Also, the ratio of resistor R₁ to resistor R₂ provides an acceptable level of the second signal 202 to provide an input to the processor 300.

The resistor R₃ is 5 Meg-Ohms, which is much greater than R_{L}.

The capacitor C₁ is 100 pF, which is greater than 1/(2□R₃ f₀).

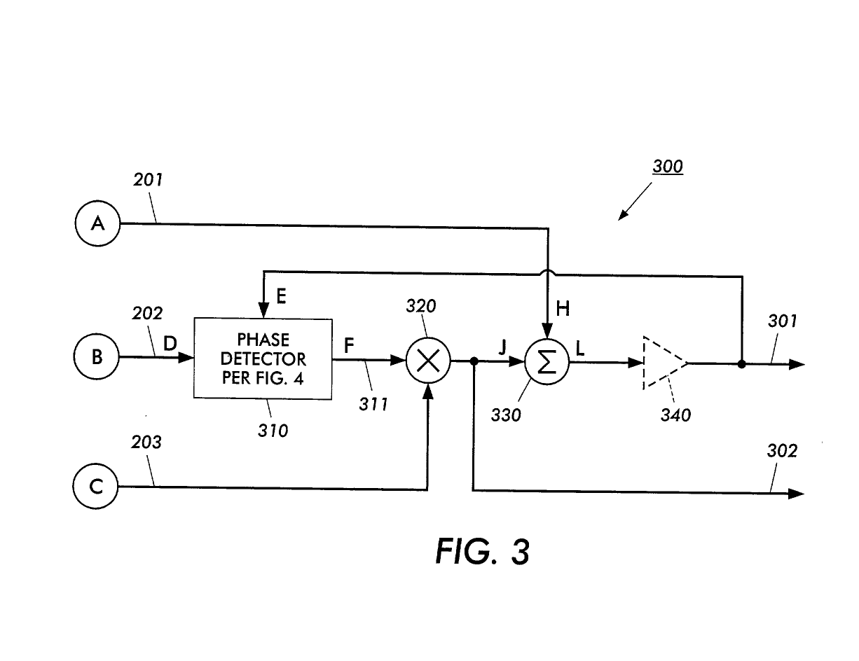

Refer now to FIG. 3. As depicted therein, the FIG. 2 processor 300 comprises a phase detector 310, a multiplier 320 and a summing circuit 330, with the FIG. 2 first, second and third signals 201-203 coupled as shown. The FIG. 3 phase detector 310 forms an intermediate result 311 based on the phase difference between the first result 301 and the second signal 202. The intermediate result 311 and the third signal 203 are then multiplied by the multiplier 320 to form a FIG. 3 second result 302 that is proportional to the capacitive current, I_{X}. The summing circuit 330 then sums the first signal 201 and the second result 302 to form the FIG. 3 first result 301.

In one embodiment, the FIG. 3 first result 301 is equal in volts to the resistive current (I_{R}) times the sense resistor (R_{S}).

In one embodiment, the FIG. 3 second result 302 is equal in volts to the capacitive current (I_{X}) times the sense resistor (R_{S}).

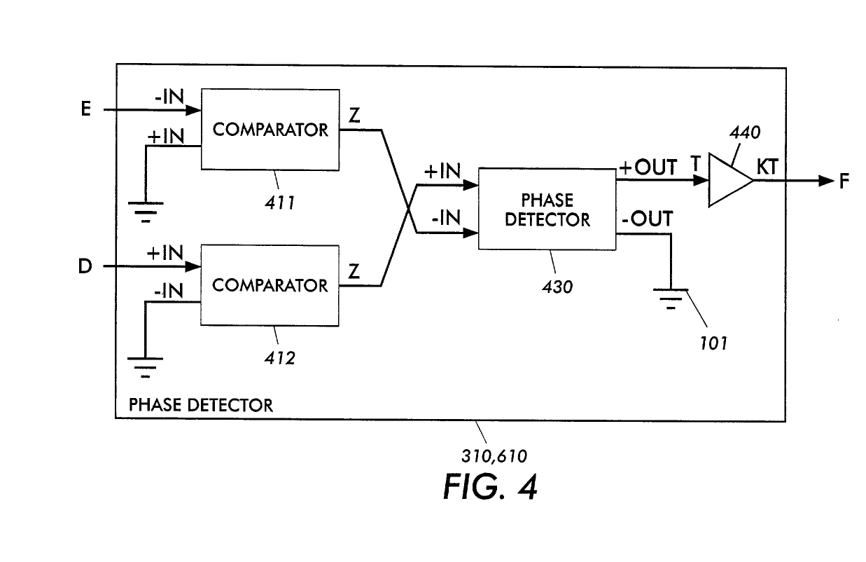

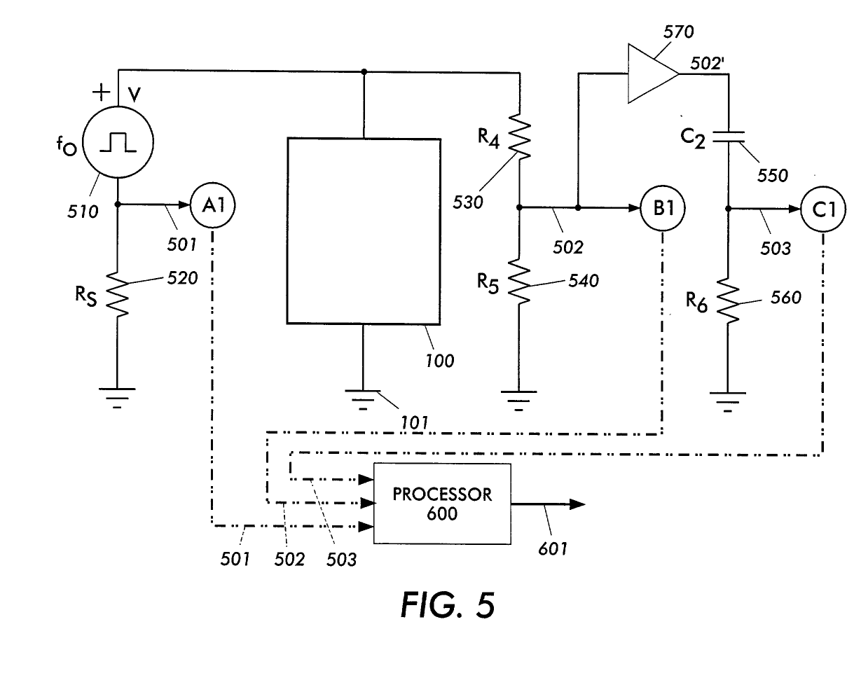

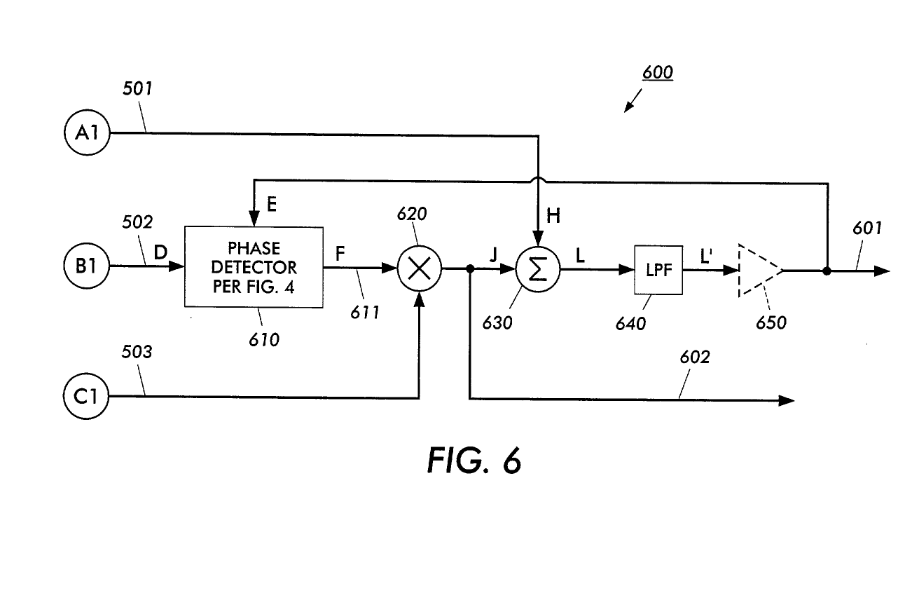

The FIG. 3 phase detector 310 is depicted in greater detail in FIG. 4, which is discussed below.

Still referring to FIG. 3, in one embodiment, the multiplier 320 comprises an analog four-quadrant multiplier IC, such as, for example, the Analog Devices part number AD532, available from Analog Devices, One Technology Way, Norwood, Mass. 02062, whose web site address is: www.analog.com.

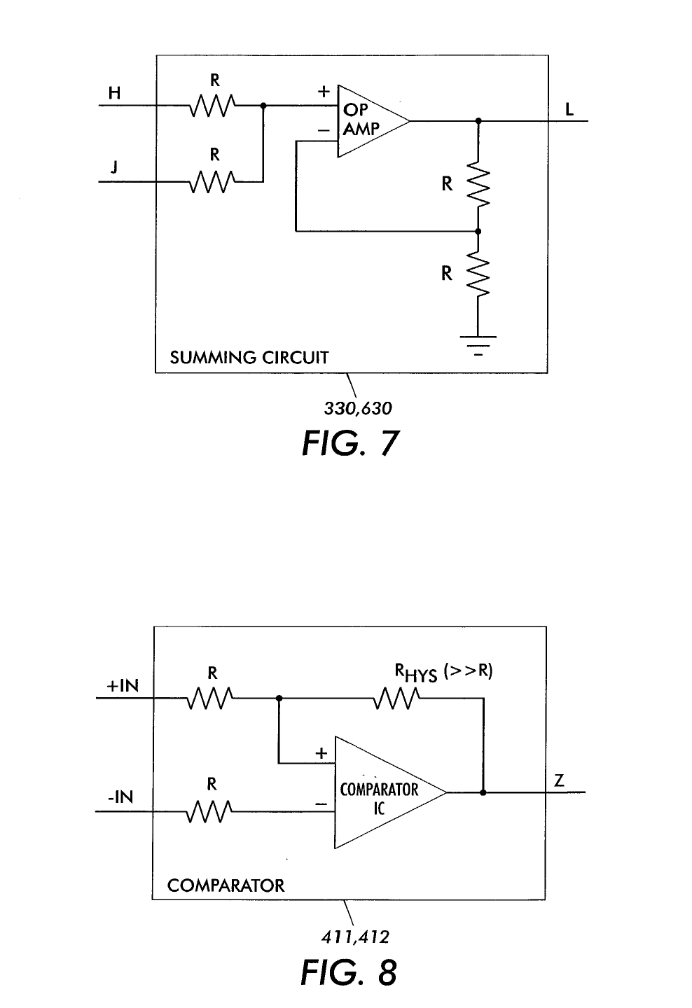

The FIG. 3 summing circuit 330, for example, may comprise the summing circuit that is depicted in FIG. 7.

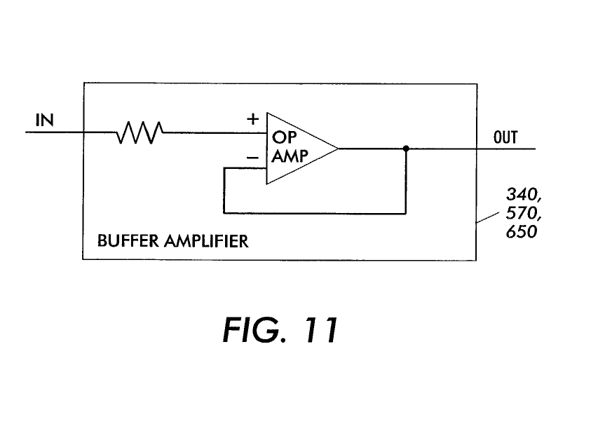

Still referring to FIG. 3, in one embodiment, a unity-gain buffer amplifier 340, depicted in broken lines, is coupled in series with the summing circuit 330 output. The FIG. 3 buffer amplifier 340, for example, may comprise the buffer amplifier that is depicted in FIG. 11.

Referring now to FIG. 4, there is depicted the FIG. 3 phase detector 310 and the identical FIG. 6 phase detector 610.

Still referring to FIG. 4, as depicted therein, the detector 310 comprises a first comparator 411, a second comparator 412, a phase detector 430 and an amplifier 440. The amplifier 440 has a gain of K.

Each comparator of the FIG. 4 first comparator 411 and second comparator 412, for example, may comprise the comparator that is depicted in FIG. 8.

In one embodiment, the FIG. 4 phase detector 430 comprises a phase detector IC such as, for example, the National Semiconductor part number 74C932, available from National Semiconductor, 2900 Semiconductor Drive, Santa Clara, Calif. 95052, whose web site is: www.national.com.

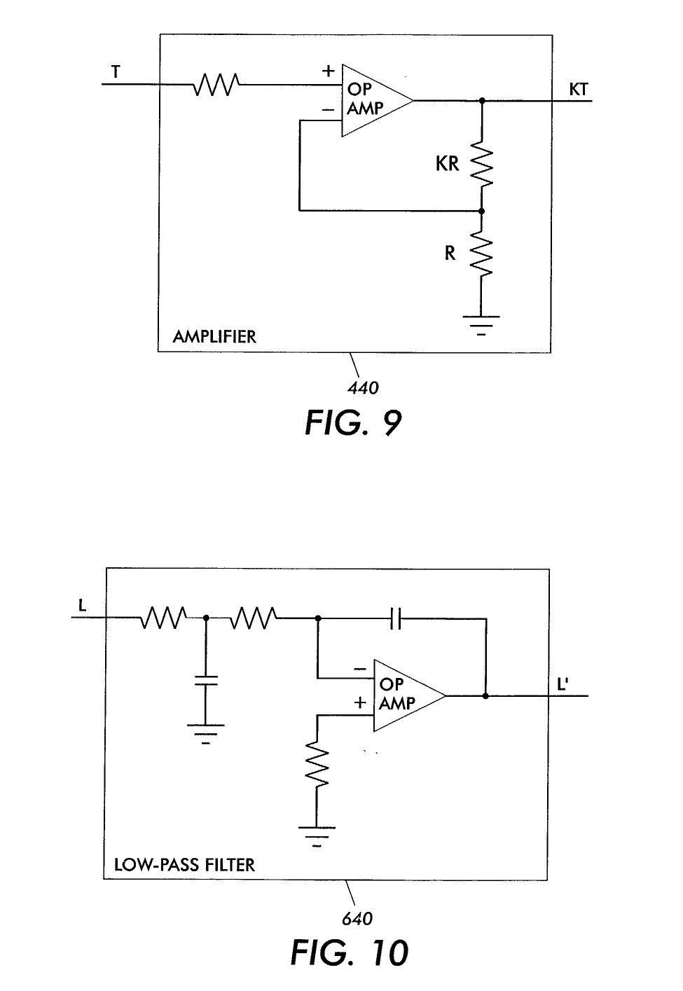

The FIG. 4 amplifier 440, for example, may comprise the amplifier circuit that is depicted in FIG. 9.

In one embodiment, the accuracy of the FIG. 3 first result 301 as a measure of the resistive current, I_{R}, is based on the value of the FIG. 4 amplifier 440's gain, K. As well, the accuracy of the FIG. 3 second result 302 as a measure of the capacitive current, I_{X}, likewise is based on the value of the FIG. 4 amplifier 440's gain, K. Generally, K equals the inverse of the desired accuracy. For example, for 1% accuracy, then K equals the inverse of 1%, or 1/0.01, thus K equals 100. As another example, for 0.1% accuracy, then K equals the inverse of 0.1%, or 1/0.001, thus K equals 1000.

Referring to FIG. 5, there is depicted the input signal 510, comprising a non-sinusoidal input signal of frequency f₀, and the FIG. 1 load 100 arranged for determining the resistive current, I_{R}.

In one embodiment, for example, the input signal 510 comprises a square wave.

A first signal 501 is formed based on a sense resistor (R_{S}) 520 coupled in series with the input signal 510. This FIG. 5 first signal 501 is in-phase with and proportional to the sum at all frequencies comprised in the input signal 510 of the resistive current, I_{R}, and the capacitive current, I_{X}.

A second signal 202 is formed based on a resistive voltage-divider network comprising resistor 530 (R₄) and resistor 540 (R₅) coupled from the input signal 510 to ground 101. This FIG. 5 second signal 502 is in-phase with the input signal 510.

A third signal 503 is formed based on a capacitor-resistor network comprising capacitor 550 (C₂) and resistor 560 (R₆) coupled from the second signal 502 to ground 101. A unity-gain buffer amplifier 570 is coupled in series with the second signal 502. The FIG. 5 buffer amplifier 570, for example, may comprise the buffer amplifier that is depicted in FIG. 11.

The FIG. 5 third signal 503 is proportional to the capacitive current, lx, at all frequencies comprised in the input signal 510.

The FIG. 5 first, second and third signals 501-503 are then input to a processor 600 which forms a first result 601 that is proportional to the resistive current, I_{R}.

In one embodiment:

The input signal 510 comprises a non-sinusoidal signal of magnitude of 6 Kilo volts RMS at a frequency (f₀) of 4 KHz.

The load resistance R_{L}, comprising the load charging device 100 corona charging resistance, comprises 500 K-Ohms.

The load capacitance C_{L}, representing the load charging device 100 parasitic capacitance, comprises 10 pF.

The sense resistor, R_{S}, comprises 100 ohms, which is much less than R_{L}.

The resistor R₄ is 10 Meg-Ohms, and the resistor R₅ is 10 K-Ohms. Thus, the sum of resistor R₄ and resistor R₅ is much greater than R_{L}. Also, the ratio of resistor R₄ to R₅ provides an acceptable level of the second signal 502 to be used as input to the processor 600.

The resistor R₆ is 100K-Ohms.

The capacitor C₂ is 0.001 micro-F.

Referring to FIG. 6, as depicted therein, the FIG. 5 processor 600 comprises a phase detector 610, a multiplier 620, a summing circuit 630 and a low-pass filter 640, with the FIG. 5 first, second and third signals 501-503 coupled as shown. The phase detector 610 forms an intermediate result 611 based on the phase difference between the first result 601 and the second signal 502. The intermediate result 611 and the third signal 503 are then multiplied by the multiplier 620 to form a FIG. 6 second result 602 that is proportional to the capacitive current, I_{X}. The summing circuit 630 then sums the first signal 501 and the second result 602 to form a sum L. The sum L is then filtered by the low-pass filter 640 to form a filtered output L′, and ultimately the FIG. 6 first result 601.

In one embodiment, the FIG. 6 first result 601 is equal in volts to the resistive current (I_{R}) times the sense resistor (R_{S}).

In one embodiment, the FIG. 6 second result 602 is equal in volts to the capacitive current (I_{X}) times the sense resistor (R_{S}).

Still referring to FIG. 6, the phase detector 610 is depicted in greater detail in FIG. 4, which is discussed above.

As discussed above in connection with the FIG. 4-depicted phase detector 610, it will be understood the phase detector 610 comprises an amplifier 440 with a gain of K. In one embodiment, the accuracy of the FIG. 6 first result 601 as a measure of the resistive current, I_{R}, is based on the value of K. As well, the accuracy of the FIG. 6 second result 602 as a measure of the capacitive current, I_{X}, likewise is based on the value of K. Generally, K equals the inverse of the desired accuracy.

Still referring to FIG. 6, in one embodiment, the multiplier 620 comprises an analog four-quadrant multiplier IC, such as, for example, the Analog Devices part number AD532.

The FIG. 6 summing circuit 630, for example, may comprise the summing circuit that is depicted in FIG. 7.

In one embodiment, the FIG. 6 low-pass filter 640 has a cut-off frequency equal to 10 times f₀. The FIG. 6 low-pass filter 640, for example, may comprise the low-pass filter that is depicted in FIG. 10.

Still referring to FIG. 6, in one embodiment, a unity-gain buffer amplifier 650, depicted in broken lines, is coupled in series with the low-pass filter 640 output L′. The FIG. 6 buffer amplifier 650, for example, may comprise the buffer amplifier that is depicted in FIG. 11.

Referring to FIG. 7, there is depicted a typical summing circuit that, for example, may comprise the FIG. 3 summing circuit 330 and the FIG. 6 summing circuit 630. The FIG. 7-depicted Op Amp is a typical Op Amp IC such as, for example, the Maxim part number MAX400 available from Maxim Dallas Semiconductors, 120 San Gabriel Drive, Sunnyvale, Calif. 94086, whose web site is: www.maxim-ic.com.

Referring to FIG. 8, there is depicted a typical comparator that, for example, may comprise the FIG. 4 first comparator 411 and the second comparator 412. The FIG. 8-depicted comparator IC is a typical analog comparator IC such as, for example, the National Semiconductor part number LM311 available from National Semiconductor. Note the value of the hysteresis resistor (R_{HYS}) is much greater than the value of either input resistor R.

Referring to FIG. 9, there is depicted a typical amplifier circuit that, for example, may comprise the FIG. 4 amplifier circuit 440. The FIG. 9-depicted Op Amp is a typical OP Amp IC such as, for example, the Maxim part number MAX 400.

Referring to FIG. 10, there is depicted a typical low-pass filter that, for example, may comprise the FIG. 6 low-pass filter 640. The FIG. 10-depicted Op Amp is a typical OP Amp IC such as, for example, the Maxim part number MAX 400. It is well-known to select the FIG. 10-depicted resistor and capacitor values to achieve the designed filter performance.

Referring to FIG. 11, there is depicted a typical buffer amplifier that, for example, may comprise the FIG. 3 buffer amplifier 340, the FIG. 5 buffer amplifier 570, and the FIG. 6 buffer amplifier 650. The FIG. 11-depicted Op Amp is a typical OP Amp IC such as, for example, the Maxim part number MAX 400.

While various embodiments of a method of determining a resistive current have been disclosed hereinabove, the scope of the invention is defined by the following claims.

What is claimed is:

1. A method of determining a resistive current of a load, the load further comprising a capacitive current, the load driven by an input signal, the input signal being sinusoidal, the method comprising:
(a) forming a first signal substantially in-phase with and proportional to the sum of the resistive current and the capacitive current;
(b) forming a second signal in-phase with the input signal;
(c) forming a third signal opposite in phase to the capacitive current; and
(d) processing the first, second and third signals to form a first result based on the resistive current.

2. The method of claim 1, the first result being in-phase with and proportional to the resistive current.

3. The method of claim 1, the processing including forming an intermediate result based on the phase difference between the first result and the second signal.

4. The method of claim 3, the processing including multiplying the intermediate result and the third signal to form a second result based on the capacitive current.

5. The method of claim 4, the second result being proportional to the capacitive current.

6. The method of claim 4, the first result based on summing the first signal and the second result.

7. The method of claim 6, the first signal based on a sense resistor in series with the input signal.

8. The method of claim 6, the second signal based on a resistive network coupled to the input signal and ground.

9. The method of claim 6, the third signal based on a resistor-capacitor network coupled to the input signal and ground.

10. The method of claim 1, the resistive current comprising a charging device corona current.

11. A method of determining a resistive current of a load, the load further comprising a capacitive current, the load driven by an input signal, the method comprising:
(a) forming a first signal in-phase with and proportional to the sum at all frequencies comprised in the input signal of the resistive current and the capacitive current;
(b) forming a second signal in-phase with the input signal;
(c) forming a third signal proportional to the capacitive current at all frequencies comprised in the input signal; and
(d) processing the first, second and third signals to form a first result based on the resistive current.

12. The method of claim 11, the first result being in-phase with and proportional to the resistive current.

13. The method of claim 11, the processing including forming an intermediate result based on the phase difference between the first result and the second signal.

14. The method of claim 13, the processing including multiplying the intermediate result and the third signal to form a second result based on the capacitive current.

15. The method of claim 14, the second result being proportional to the capacitive current.

16. The method of claim 14, the first result based on summing and low-pass filtering the first signal and the second result.

17. The method of claim 16, the first signal based on a sense resistor in series with the input signal.

18. The method of claim 16, the second signal based on a resistive network coupled to the input signal and ground.

19. The method of claim 16, the third signal based on a capacitor-resistor network coupled to the second signal and ground.

20. The method of claim 11, the resistive current comprising a charging device corona current.

21. The method of claim 11, the input signal comprising a square wave.
